(19) United States
(12) Patent Application Publication
(10) Pub. No.: US 2024/0128051 A1
(43) Pub. Date: Apr. 18, 2024

(54) MULTI-BEAM CHARGED PARTICLE BEAM SYSTEM WITH ANISOTROPIC FILTERING FOR IMPROVED IMAGE CONTRAST

(71) Applicant: Carl Zeiss MultiSEM GmbH, Oberkochen (DE)

(72) Inventors: Dirk Zeidler, Oberkochen (DE); Bjoern Miksch, Heidenheim (DE); Maksym Kompaniiets, Weissenhorn (DE)

(21) Appl. No.: 17/966,026

(22) Filed: Oct. 14, 2022

(51) Int. Cl. H01J 37/317; H01J 37/12

(52) U.S. Cl. CPC H01J 37/3177; H01J 37/12; H01J 2237/0435; H01J 2237/1536; H01J 2237/24592

(57) ABSTRACT

A multi-beam charged particle system and a method of operating a multi-beam charged particle system can provide improved image contrast. The multi-beam charged particle system comprises a filter element or an active array element in a detection system, which can provide improved, anisotropic image contrast. The disclosure can be applied for applications of multi-beam charged particle system, where higher requirements on beam uniformity and throughput may be relevant.

### FIELD

The disclosure relates to a multi-beam charged particle microscope that can provide improved imaging contrast and a method for the inspection of semiconductor features that can provide improved image contrast.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. The primary charged particle beamlets are focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated in the usual way of scanning electron microscopes.

Generally, the imaging contrast of a scanning electron microscope generally depends on the signal generated by secondary electrons, which generally depends on the secondary electron (SE) yield per primary electron and a geometrical collection efficiency of the electron microscope. The SE yield generally depends on material characteristics and the kinetic energy of the primary electrons. The SE yield typically has an angular component, i.e. the SE yield is a typically a function of the polar angle with respect to a surface normal to the sample. In other examples, the SE yield might be influenced by topography effects of the sample surface.

Different contrast mechanisms have been proposed to improve an imaging contrast of a multi-beam electron microscope. U.S. Pat. No. 11,049,686 BB proposes an arrangement of circular of annular aperture filters within a pupil plane of the secondary electron imaging system. In German patent application DE 102021124099.9, filed on Sep. 17, 2021, a multi-beam electron microscope is disclosed with a detector capable of detecting an angular component of each secondary beamlet. Thereby, an image contrast can be improved by selecting appropriate angular components. The disclosed system offers a large degree of flexibility at the expense of large efforts in a highly complex detection system, involving even more high-speed signal channels. Furthermore, by separating a secondary electron signal in several angular components, the system is more sensitive to noise and might involve larger dwell times or larger primary electron currents.

### SUMMARY

The disclosure seeks to provide a multi-beam charged particle system and a method of operating a multi-beam charged particle system for image acquisition high higher contrast. This can involve anisotropic filtering of the secondary electron beamlets with a selected aperture filter. In an example, the anisotropic filtering of at least one secondary electron beamlet is achieved by applying a selected anisotropic shaping of the secondary electron beamlet in conjunction with a selected aperture filter. In an example, an aperture filter of anisotropic shape is applied, for example with an elongated rectangular or elliptical aperture, or a dipole or quadrupole filter comprising two or four off-axis aperture openings. With the anisotropic filtering according to the disclosure, an image contrast of a semiconductor feature of interest can be enhanced. This can yield, for example, increased measurement accuracy.

According to an aspect, the disclosure provides a multi-beam charged particle beam system for wafer inspection. The system can offer relatively high flexibility for different image contrast methods. The multi-beam charged particle beam system comprises an object irradiation unit with a multi-beamlet generator for generating a plurality of primary charged particle beamlets. The multi-beam charged particle beam system comprises an objective lens for focusing during use the plurality of primary charged particle beamlets into an image plane of the object irradiation unit. During use, a plurality of secondary electron beamlets is generated at the interaction volumes of the plurality of primary charged particle beamlets with the wafer. The multi-beam charged particle beam system further comprises a detection unit configured for imaging a plurality of secondary electron beamlets onto an image sensor. The multi-beam charged particle beam system also comprises a beam splitter unit for guiding the plurality of primary charged particle beamlets from the multi-beamlet generator to the objective lens and for guiding the plurality of secondary electron beamlets from the objective lens to the detection unit. The detection unit comprises an aperture filter module with at least one selected aperture filter for anisotropic filtering at least one secondary electron beamlet. The multi-beam charged particle beam system further comprises a control unit with a contrast control module. The contrast control module is configured for controlling during use a selected anisotropic filtering of at least one of the secondary electron beamlets with the selected aperture filter of the aperture filter module.

The multi-beam charged particle beam system can further comprise a voltage supply unit connected during us to a wafer for providing during use a voltage to the wafer for generating a decelerating field for primary charged particles, corresponding to an accelerating or extraction field for the secondary electrons generated in the interaction volumes. The detection unit can comprise a plurality of electron-optical elements, for example configured for forming a cross over plane or common pupil plane of the secondary electron beamlets, where the plurality of secondary beamlets form a cross over.

The secondary electron yield at each interaction volume generally depends on the current of corresponding primary charged particle beamlet, the material composition within the interaction volume. The angular distribution of the secondary electrons generally depends on local charging effects of semiconductor features, including semiconductor features in underlying layers of a wafer, local influences of the extraction field for secondary electrons, or a local topography of the wafer surface in proximity of the interaction volume.

With the anisotropic filtering, secondary electrons from underlying semiconductor features or underlying background can be at least partially blocked or filtered out during an inspection. With a selected anisotropic filtering according to the disclosure, an image contrast of a semiconductor feature of interest can be enhanced. This can, for example, increase measurement accuracy.

In an example, the aperture filter module comprises a movement mechanism configured for exchanging the at least one aperture filter. The contrast control module can be configured for selecting and positioning during use a selected aperture filter with the movement mechanism in a common pupil plane of the detection unit. In an example, a selected aperture filter comprises an aperture opening of anisotropic shape, for example of elliptical shape or elongated rectangular shape. In an example, a selected aperture filter comprises a plurality of aperture openings configured to be arranged outside of an electron optical axis of the detection unit. For example, a selected aperture filter comprises at least two aperture openings arranged symmetrically with respect to the electron optical axis for forming an aperture filter with dipole or quadrupole openings. In an example, the contrast control module is configured to arrange the aperture filter with dipole or quadrupole shape according to the horizontal or vertical structures of semiconductor features in a wafer. In an example, the contrast control module is configured to arrange the aperture filter with dipole or quadrupole shape according to a topography of semiconductor features in a wafer.

In an example, the plurality of electron-optical elements of the detection unit is further configured for forming an intermediate image plane of the plurality of secondary electron beamlets. The detection unit can further comprises an active multi-aperture array arranged in proximity to the intermediate image plane at a distance, where the plurality of secondary electron beamlets do no overlap or intersect. The active multi-aperture array can comprise a plurality of apertures, each for passage of one of the plurality of secondary electron beamlets, and each of the apertures is configured with a plurality of electrodes connected to the contrast control module. The active multi-aperture array can be configured for individually shaping or deflecting during use each of the secondary electron beamlets. For example, the contrast control module can be configured for controlling the active multi-aperture array for a first anisotropic shaping or first deflecting of a first secondary electron beamlet and for a second anisotropic shaping or second deflecting of a second secondary electron beamlet. The contrast control module can be further configured to arrange a selected aperture filter of circular shape in the common pupil plane. Thereby, a different anisotropic filtering of a first and second secondary electron beamlet can be achieved, and an imaging contrast of the multi-beam charged particle beam system is improved for each of the plurality of charged particle beamlets. Secondary electrons from local underlying semiconductor features or local background can be at least partially blocked or filtered out for each of the plurality of primary charged particle beamlets. With the different anisotropic filtering, larger areas of a wafer with different semiconductor features can be inspected with large imaging contrast, and an inspection task can be performed with higher reliability and larger accuracy.

In an example, the contrast control module is configured to determine the anisotropic filtering of each of the plurality of secondary electron beamlets to achieve an increased image contrast. In an example, the contrast control module is configured to modify an anisotropic filtering to iteratively improve and optimize an image contrast. In an example, the contrast control module is configured to select an anisotropic filtering according to prior information, for example based on stored information of a selected anisotropic filtering for an inspection site, or based on CAD information of semiconductor features of a wafer.

According to an aspect, the disclosure provides a method of contrast improvement for a wafer inspection task. The method comprises the step of illuminating a surface of a wafer with a plurality of primary charged particle beamlets of a multi-beam charged particle beam system. Thereby, a plurality of secondary electron beamlets is excited from a plurality of interaction volumes generated by the plurality of primary charged particle beamlets with the wafer. The method comprises the step of collecting the plurality of secondary electron beamlets with an objective lens and the step of anisotropic filtering at least one of the secondary electron beamlets by a selected aperture filter. The method comprises the step of collecting the signals of each of the plurality of secondary electron beamlets with an image sensor, including the at least one anisotropically filtered secondary electron beamlet, for generating an image of a surface of a wafer with enhanced contrast of a semiconductor feature of interest. The selected aperture filter arranged in a common pupil plane of a detection unit of the multi-beam charged particle beam system. With the anisotropic filtering, secondary electrons from underlying semiconductor features or underlying background can be at least partially blocked or filtered out during an inspection.

In an example, the method further comprises the steps of selecting the selected aperture filter and positioning the selected aperture filter with a movement mechanism in the common pupil plane of the detection unit. A movement mechanism can comprise a linear or rotary slider. In an example, the method further comprises the step of providing to at least one electrode of an active array element a voltage for anisotropically shaping or deflecting at least one of the secondary electron beamlets. With an active array element arranged within the detection unit (200), each secondary electron beamlet can individually be shaped in an anisotropic form, for example an elliptical form, or by providing an isotropic shape with a lateral offset.

According to an example, the method further comprises the steps of arranging an inspection position of a surface of a wafer in the image plane of the multi-beam charged particle beam system, determining a selected contrast mechanism at the inspection position, and selecting and providing a selected aperture filter and at least one of a plurality of voltages to an active array element according to the selected contrast mechanism, and performing an image acquisition of the surface of a wafer. Thereby, a digital image of semiconductor features of the wafer can be acquired at the inspection position. The inspection position of a surface of a wafer is typically arranged with a wafer stage comprising six axis control and for example an interferometer for precision control of position and alignment. With the selected aperture filter and the at least one of a plurality of voltages to an active array element, at least one of the secondary electron beamlets can be anisotropically filtered, and a first image contrast of the digital image is in increased. In an example, the method further comprises a step of evaluating a first image contrast of the digital image and a step of modifying the selected contrast mechanism by modifying at least one of the selected aperture filter or a voltage provided to an electrode of the active array element. An image acquisition of the surface of a wafer can be repeated with the modified contrast mechanism and an improved contrast mechanism is determined with improved image contrast compared to the first image contrast. In an example, the modified or improved contrast mechanism is stored in a memory for use with the inspection position. With the method, a contrast mechanism can be optimized for improved imaging contrast at each inspection position. A further inspection task at a comparable inspection position at for example another wafer or another die can thus be performed with a pre-determined contrast mechanism.

In an example, the method further comprises the step of performing an image evaluation of the digital image of semiconductor features of the wafer to determine a defect. A defect is generally described by at least one of an excess deviation of a size, an area, a material composition of a semiconductor feature, or an excess feature, for example a contamination particle. In an example, the method further comprises the step of repeating the image acquisition of the surface of a wafer at plural inspection positions, for example including a first and a second, different contrast mechanism, and a step of evaluating a distribution of defects to determine at least one of random defects, regular defects or clusters of defects.

In an aspect, the disclosure provides a multi-beam charged particle beam system that comprises an object irradiation unit, which comprises: a multi-beamlet generator configured to generate a plurality of primary charged particle beamlets; and an objective lens configured to focus the plurality of primary charged particle beamlets into an image plane of the object irradiation unit. The multi-beam charged particle beam system also comprises: a detection unit configured to image a plurality of secondary electron beamlets generated via interaction of the plurality of primary charged particle beamlets with a surface of a wafer onto an image sensor, wherein the detection unit comprises an aperture filter module comprising an aperture filter configured to anisotropically filter at least one secondary electron beamlet; a beam splitter unit configured to guide the plurality of primary charged particle beamlets from the multi-beamlet generator to the objective lens and to guide the plurality of secondary electron beamlets from the objective lens to the detection unit; and a control unit comprising a contrast control module configured to control anisotropic filtering of the at least one of the plurality of secondary electron beamlets via the aperture filter.

In some embodiments, the aperture filter module comprises a movement mechanism configured to exchange the aperture filter, and the contrast control module is configured to select and position the aperture filter via the movement mechanism in a common pupil plane of the detection unit.

In some embodiments, the aperture filter comprises an anisotropically shaped aperture opening.

In some embodiments, the aperture filter comprises a member selected from an elliptical aperture filter and an elongated rectangular aperture filter.

In some embodiments, the aperture filter comprises a plurality of aperture openings outside an electron optical axis of the detection unit.

In some embodiments, at least two of the plurality of aperture openings are disposed symmetrically with respect to the electron optical axis to provide an aperture filter with a shape selected from a dipole shape and a quadrupole shape.

In some embodiments, the contrast control module is configured to arrange the aperture filter with the shape based on structures of semiconductor features in the wafer that are selected from horizontal structures and vertical structures.

In some embodiments, the contrast control module is configured to arrange the aperture filter with the shape based on a topography of semiconductor features in the wafer.

In some embodiments, the detection unit comprises: a plurality of electron-optical elements configured to provide an intermediate image plane of the plurality of secondary electron beamlets; and an active multi-aperture array in proximity to the intermediate image plane, the active multi-aperture array comprising a plurality of apertures, each aperture of the multi-aperture array configured to pass one of the plurality of secondary electron beamlets, each aperture of the multi-aperture array comprising a plurality of electrodes connected to the contrast control module to individually anisotropically shape or deflect the one of the plurality of secondary beamlets that passes therethrough.

In some embodiments: the contrast control module is configured to control the active multi-aperture array to: i) anisotropically shape or deflect a first secondary electron beamlet; and anisotropically shape or deflect of a second secondary electron beamlet; and the contrast control module is configured to arrange a circular aperture filter in a common pupil plane of the detection unit.

In some embodiments, the multi-beam charged particle beam system further comprises a voltage supply unit configured to be connected to the wafer to provide a voltage to the wafer to generate a decelerating field for primary charged particles, corresponding to an accelerating field for the secondary electrons.

In an aspect, the disclosure provides a method, comprising: using a plurality of primary charged particle beamlets of a multi-beam charged particle beam system to illuminate a surface of a wafer to generate a plurality of secondary electron beamlets generated by the plurality of primary charged particle beamlets and the wafer; using an objective lens to collect the plurality of secondary electron beamlets; using a selected aperture filter arranged in a common pupil plane of a detection unit of the multi-beam charged particle beam system to anisotropically filter a secondary electron beamlet; and using an image sensor to collect the signals of each of the plurality of secondary electron beamlets, including the anisotropically filtered secondary electron beamlet, to generate an image of a surface of the wafer.

In some embodiments, the method further comprises: selecting the aperture filter; and positioning the selected aperture filter in the common pupil plane of the detection unit.

In some embodiments, the method further comprises providing a voltage to an electrode of an active array element arranged within the detection unit to anisotropically shape or deflect at least one of the secondary electron beamlets.

In some embodiments, the method further comprises: arranging an inspection position of a surface of the wafer in the image plane of the multi-beam charged particle beam system; determining a selected contrast mechanism at the inspection position; selecting and providing the aperture filter and at least voltage to an active array element to anisotropically filter at least one of the secondary electron beamlets according to the selected contrast mechanism; and performing an image acquisition of the surface of the wafer to acquire a digital image of semiconductor features of the wafer at the inspection position.

In some embodiments, the selected contrast mechanism at the inspection position is determined according to information comprising a member selected from: i) a previously determined selected contrast mechanism at an equivalent inspection position; and ii) CAD information.

In some embodiments, the method further comprises: evaluating a first image contrast of the digital image; modifying the selected contrast mechanism by modifying at least one member selected from the group consisting of the preselected aperture filter and a voltage provided to an electrode of the active array element; and determining a second contrast mechanism with improved image contrast compared to the first image contrast.

In some embodiments, the method further comprises storing the second contrast mechanism to be used with the inspection position.

In some embodiments, the method further comprises performing an image evaluation of the digital image of semiconductor features of the wafer to determine a defect comprising at least one member selected from the group consisting of a deviation of a size of a semiconductor feature, a deviation of an area of a semiconductor feature, a deviation of a material composition of a semiconductor feature, and a contamination particle.

In some embodiments, the method further comprises: repeating the image acquisition of the surface of the wafer at plural inspection positions; and evaluating a distribution of defects to determine at least one member selected from the group consisting of random defects, regular defects, and clusters of defects.

By the embodiments or examples of the disclosure, the disclosure provides a multi-beam charged particle beam system which can offer improved image contrast and a method of operating a multi-beam charged particle beam system which can offer improved image contrast. The disclosure can allows wafer inspection with relatively high precision and with relatively high accuracy.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system according;

FIG. 2 illustrates some example of aperture filters of an aperture filter module;

FIG. 3 illustrates an example of semiconductor features in a multi-layer structure of a wafer;

FIG. 4 illustrates an example of semiconductor features having a topography;

FIG. 5 illustrates an active array element;

FIGS. 6A-6C illustrate anisotropically filtering two out of three secondary electron beamlets with the active array element;

FIG. 7 illustrates an example of a method according to the second embodiment;

FIGS. 8A-8C illustrate anisotropic filtering on an image contrast; and

FIG. 9 illustrates a defect classification on a wafer surface.

### DESCRIPTION OF EXEMPLARY EMBODIMENTS

In the exemplary embodiments of the disclosure described below, components similar in function and structure are indicated as far as possible by similar or identical reference numerals.

Some array elements, for example the plurality of primary charged particle beamlets, are identified by a reference number. Depending on the context, the same reference number may also identify a single element out or the array elements. Each primary charged particle beamlet (3.1, 3.2, 3.3) is one of the plurality of primary charged particle beamlets (3).

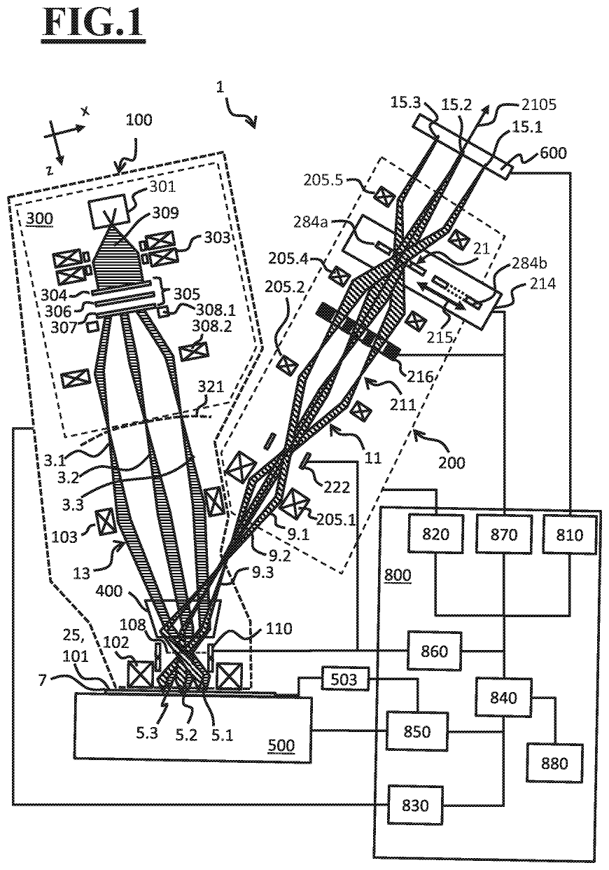

The schematic representation of FIG. 1 illustrates basic features and functions of a multi-beam charged-particle system 1 according to a first embodiment of the disclosure. It is to be noted that the symbols used in the figure have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface 25 in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles, such as ions, for example, Helium ions. Further details of the microscope system 1 are provided in International Patent application PCT/EP2021/066255, filed on Jun. 16, 2021, which is hereby fully incorporated by reference.

The system 1 comprises an object irradiation unit (100) and a detection unit 200 and a secondary electron beam divider or beam splitter unit 400 for separating the secondary charged-particle beam path 11 from the primary charged-particle beam path 13. The object irradiation unit 100 comprises a charged-particle multi-beam generator 300 for generating the plurality of primary charged-particle beamlets 3 and is adapted to focus the plurality of primary charged-particle beamlets 3 on the object plane 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 usually includes one or more electrostatic or magnetic lenses, or by a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355 B1, both hereby incorporated by reference. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generating the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 according to some embodiments is configured with a terminating multi-aperture plate 307. The multi-beamlet forming unit 305 is further configured with an adjacent electrostatic field lenses 308.1, which is in some examples combined in the multi-beamlet forming unit 305. Together with a second field lens 308.2, the plurality of primary charged particle beamlets 3 is focused in or in proximity of the intermediate image surface 321. The primary charged-particle source 301 and each of the active multi-aperture plates 306 are controlled by control unit 800.

The plurality of focus points of primary charged particle beamlets 3 passing the intermediate image surface 321 is imaged by field lens group 103 and objective lens 102 into the object plane 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a landing energy of primary electrons is adjusted to for example below 1 keV, below 500 eV, below 300 eV or even less.

The object irradiation system 100 further comprises a collective multi-beam raster scanner 110 in proximity of a beam cross over 108 by which the plurality of charged particle beamlets 3 can be deflected in a direction perpendicular to the propagation direction of the charged particle beamlets. The propagation direction of the primary beamlets throughout the examples is in the positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm and a diameter of below 5 nm, for example 3 nm, 2 nm or even below. In an example, the beam spot size is about 1.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the sample at the beam spot 5. The plurality of secondary charged particle beamlets 9 are accelerated by the same electrostatic field between objective lens 102 and object surface 25, generated by voltage supply 530, and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by secondary electron beam divider or beam splitter unit 400 to follow the secondary beam path 11 to the detection unit 200. The plurality of secondary electron beamlets 9 travels in the opposite direction from the primary charged particle beamlets 3, and the beam splitter unit 400 is configured to separate the secondary beam path 11 from the primary beam path 13 usually via magnetic fields or a combination of magnetic and electrostatic fields.

Detection unit 200 images the secondary electron beamlets 9 onto the image sensor 600 to form there a plurality of secondary charged particle image spots 15. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in U.S. Pat. No. 9,536,702, which are hereby incorporated by reference.

Detection unit 200 further comprises at least a second collective raster scanner 222, which is connected to scanning and imaging control unit 860. Scanning control unit 860 is configured to compensate a residual difference in position of the plurality of focus points 15 of the plurality of secondary electron beamlets 9, such that the positions of the plurality secondary electron focus spots 15 are kept constant at image sensor 600.

The detection unit 200 comprises further electrostatic or magnetic lenses 205.1 to 205.5 and a second cross over 21 of the plurality of secondary electron beamlets 9, in which a contrast aperture filter module 214 is located. The second cross over corresponds to a pupil plane 21 of the detection unit 200. In a pupil plane, a lateral coordinate with respect to the optical axis 2105 corresponds to a propagation angle of a secondary electron trajectory at the image plane 101. The propagation angle of a secondary electron trajectory is measured relative to the wafer surface normal, which corresponds to the optical axis 2105 of the detection unit 200. The detection unit 200 further comprises at least a first multi-aperture corrector 216, with apertures and electrodes for individual influencing each of the plurality of secondary electron beamlets 9. The multi-aperture corrector 216 is arranged in proximity to an intermediate image plane 211, where the secondary electron beamlets are separated from each other.

The image sensor 600 is configured by an array of sensing areas in a pattern compatible to the raster arrangement of the secondary electron beamlets 9 focused by the projecting lenses 205 onto the image sensor 600. This allows for detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In some embodiments, the image sensor 600 can be an electron to photon conversion unit or scintillator plate arranged in the focal plane of the plurality of secondary electron particle image spots 15. In such embodiments, the image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference.

During an acquisition of an image patch by scanning the plurality of primary charged particle beamlets 3, the stage 500 is typically not moved, and after the acquisition of an image patch, the stage 500 is moved to the next image patch to be acquired. In some implementations, the stage 500 is continuously moved in a second direction while an image is acquired by scanning of the plurality of primary charged particle beamlets 3 with the collective multi-beam raster scanner 110 in a first direction. Stage movement and stage position is usually monitored and controlled by sensors known in the art, such as Laser interferometers, grating interferometers, confocal micro lens arrays, or similar.

During an image scan, the control unit 800 triggers the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The control unit 800 of the multi-beamlet charged-particle system 1 further comprises: an imaging control module 810, configured to receive the data streams from the image sensor 600 and to generate a digital image of the surface of the sample 7 during operation; a secondary beam-path control module 820, configured to control the lenses 205 and other components of the detection unit 200; a primary beam-path control module 830, configured to control the elements of the object irradiation unit 100, including the charged-particle multi-beamlet generator 300; a stage control module 850, configured to control the stage positioning and alignment, and including control of the sample voltage supply unit 503; a scanning operation control module 860, configured to control a scanning operation by the first collective multi-beam raster scanner 110 and the second deflection system 222; a control operation processor unit 840, configured to execute inspection tasks of samples; and configured to control the modules 810, 820, 830, 850, 860, 870 and a memory 880 for storing software, instructions and image data. The control operation processor unit 840 is further connected to an interface (not shown) for exchanging data, instructions, software or user interaction.

The control unit 800 of the multi-beamlet charged-particle system 1 according to the disclosure further comprises a contrast control module 870, connected to the control operation processor unit 840. The contrast control module 870 is configured to receive instruction from the control operation processor unit 840 to control a contrast mechanism of the imaging of secondary electrons onto the image sensor 600. The contrast control module 870 is therefore connected to an aperture filter module 214 and configured to select an aperture filter 284 according to the selected contrast mechanism. For simplicity, only two different aperture filters 284a and 284b are shown, but there can be provided more than two different aperture filters 284. The aperture filters 284 can be mounted on an exchange mechanism, such as a rotary or linear moving mechanism 215 for placement of the selected aperture filter 284a in the common pupil position 21 of the plurality of secondary electron beamlets 9.

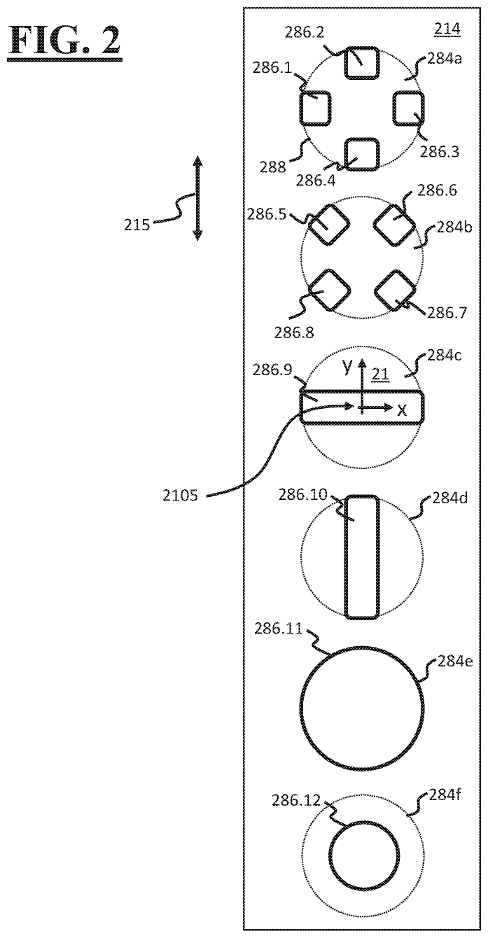

FIG. 2 illustrates examples of different apertures 284a to 284d.

According to an example, the aperture filter module 214 comprises a first aperture filter 284a with four aperture openings 286.1 to 286.4 arranged in different azimuthal locations, forming a quadrupole shaped aperture filter 284a for passing four segments of the angular spectrum of each secondary electron beamlet 9.

The aperture filter module 214 comprises a second aperture filter 284b with again four aperture openings 286.5 to 286.8 arranged in different azimuthal locations, forming a quadrupole shaped aperture filter 284b for passing four segments of the angular spectrum of each secondary electron beamlet 9, but rotated by 45° with respect to the first aperture filter 284a.

The aperture filter module 214 further comprises a third aperture filter 284c of elongated rectangular shape, configured for transmitting the angular spectrum of each secondary electron beamlet 9 in y direction to a larger extend compared to the x-direction. The third aperture filter 284c is currently centered by movement mechanism 215 at the common pupil position 2105 of the detection unit 200.

The aperture filter module 214 further comprises a fourth aperture filter 284d of elongated rectangular shape, configured for transmitting the angular spectrum of each secondary electron beamlet 9 in x direction to a larger extend compared to the y-direction. Other anisotropic shapes of aperture filters are possible as well, for example aperture filters with two decentered aperture openings (dipole filters), or with aperture openings of elliptical shape.

Generally, the multi-beam charged particle system 1 according to an example comprises at least a filter element in the detection unit 200 having an anisotropic property for generating an anisotropic image contrast. As used herein, an anisotropic property means a property that depends on the azimuthal angle with respect to a propagation direction of the secondary electron beamlet 9. Anisotropic aperture filters 284a to 284d thus do not have full rotational symmetry. Instead, their property changes with a rotation or azimuthal angle. With anisotropic aperture filters, anisotropic filtering of the angular spectrum distribution of the secondary electron beamlets 9 can be achieved. The angular spectrum distribution of a secondary electron beamlet is generally defined by the probability distribution of all possible propagation angles of individual electron trajectories within the secondary electron beamlet 9.

With the anisotropic aperture filters 284a to 284d, filtering of azimuthal components of the angular spectrum distribution of secondary electron beamlets 9 is enabled, thus allowing different contrast mechanisms during the imaging with the multi-beam charged particle system 1. The control operation processor 840 is configured to determine instructions regarding a contrast mechanism to be used for example by receiving instructions from an input or by determining instructions from a digital image output from the imaging control module 810.

The aperture filter module 214 further comprises fifth and sixth aperture filters 284e and 284f of circular shape with different radius. The application of the fifth and sixth aperture filters 284e and 284f are described below in more detail.

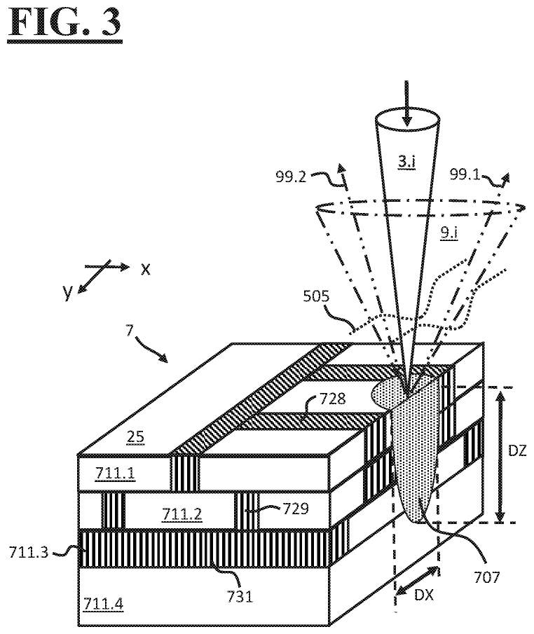

FIG. 3 illustrates an example of imaging with enhanced contrast with a secondary electron beamlet 9.i with an anisotropic angular spectrum of secondary electrons. Each primary charged particle beamlet 3, for example beamlet 3.i, in focused onto a surface 25 of a wafer sample 7 and forms there an interaction volume 707 of diameter DX and depth DZ in the wafer sample 7. The diameter DX and depth DZ typically depend on the kinetic energy after decelerating the primary charged particle beamlets 3.i. With for example 300 eV kinetic energy, the diameter DX and depth DZ are about 5 nm. With 200 eV, diameter DX and depth DZ are about 3 nm. With a kinetic energy of for example 1 keV, diameter DX increases to about 20 nm and depth to about 25 nm. Typically, a high resolution is desired, and a deceleration field is generated by sample voltage supply 503 such that the kinetic energy of primary charged particles is below 500 eV, for example 300 eV, 200 eV or even less.

Typically, a wafer sample 7 comprises several layers 711, of which only four layers 711.1 to 711.4 are shown. The layers are formed by semiconductor fabrication techniques into a silicon substrate and comprise isolators like silicon nitride, silicon oxide or silicon carbide, and metal structures like metal lines 728, 729 and 731. The metal lines 728, 729 and 731 or interconnects are arranged orthogonal to each other and are extending in either x or y-directions. During an inspection task, the metal lines 728, 729 and 731 can charge up and generate an influence of the decelerating or extraction field 505. The equipotential lines of the decelerating field 505 shows therefore local inhomogeneities. These local inhomogeneities have a minor impact of the primary charged particle beamlets 3.i, but may have a major impact on the secondary electrons generated within the interaction volume 707. Since the secondary electrons travel in the opposite direction, the decelerating field 505 for the primary charged particles forms an accelerating field 505 for the secondary electrons. The secondary electrons follow trajectories, for example trajectories 99.1 or 99.2, and are accelerated by the field with equipotential lines 505 generated by providing a voltage to the wafer 7 by voltage supply unit 503. Due to the inhomogeneity of the extraction field 505 and the inhomogeneous charge distribution in a semiconductor wafer sample 7, the secondary electrons are emitted with an uneven angular spectrum, for example with an angular spectrum of elliptical shape. In another example, the interaction volume intersects with several layers 711, for example layers 711.1 to 711.3, and within the different layers, secondary electrons are emitted with different azimuthal angular spectrum distribution. Since the metal interconnects 728, 729 or 731 are elongated in either x or y direction, the angular spectrum distribution of a secondary electron beamlet 9.i thus has pronounced spectrum distributions in x and y direction. By filtering these pronounced spectrum distributions by aperture filters 284a to 284c, the imaging contrast of for example metal line 728 is enhanced.

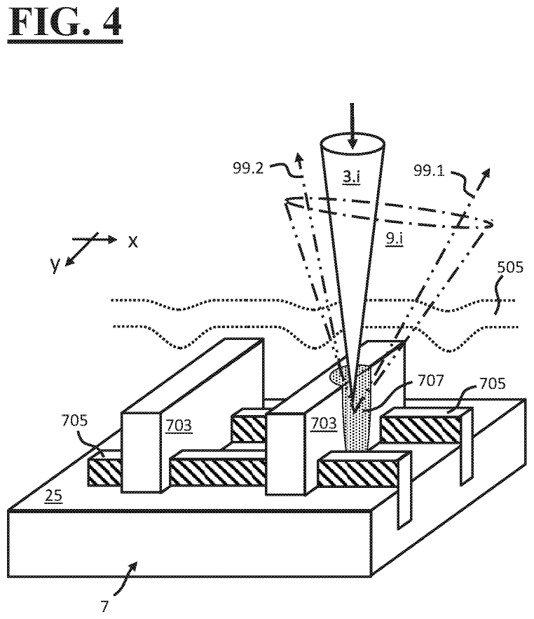

FIG. 4 illustrates a further example of an imaging with enhance contrast with a secondary electron beamlet 9.i with an anisotropic angular spectrum of secondary electrons. The primary charged particle beamlet 3.i in focused onto a surface 25 of a wafer sample 7, comprising several fins, including gate fins 703 and channel fins 705. The fins 703 and 705 form a topography on the wafer surface 25. The primary charged particle beam 3.i forms an intersection volume 707 with the topography. Due to the topography, the decelerating field 505, illustrated by equipotential lines, has local inhomogeneities. Due to the local inhomogeneities of the decelerating or extraction field 505 and due to the topography, the angular spectrum distribution of secondary electron beamlet 9.i emitted and extracted from the interaction volume shows pronounced contributions in certain azimuthal directions. Since the fins are arranged in x- and y-direction, the predominant directions of pronounced contributions to the secondary electron angular spectrum are in x or y-direction. With the aperture filters 284c or 284d, a filtering of these pronounced spectrum distributions is possible and the imaging contrast of for example gate fins 703 is enhanced and an imaging contrast of channel fins 705 is suppressed. With the aperture filter 284a, filtering the pronounced spectrum distributions is possible and the imaging contrast of gate fins 703 as well as channel fins 705 is increased over the background structures. With the anisotropic aperture filter 284b, a filtering of the pronounced angular spectrum distributions is enabled, and the imaging contrast of the background is increased and the imaging contrast of gate fins 703 as well as channel fins 705 is suppressed.

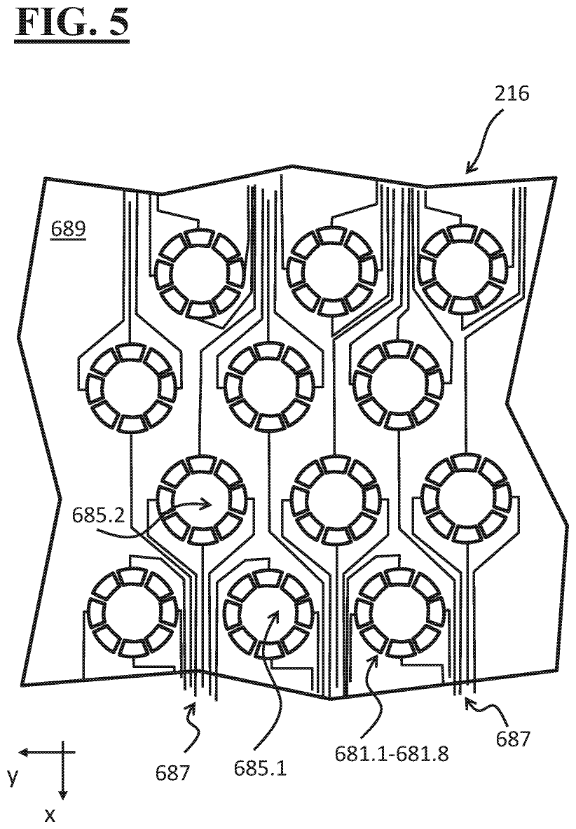

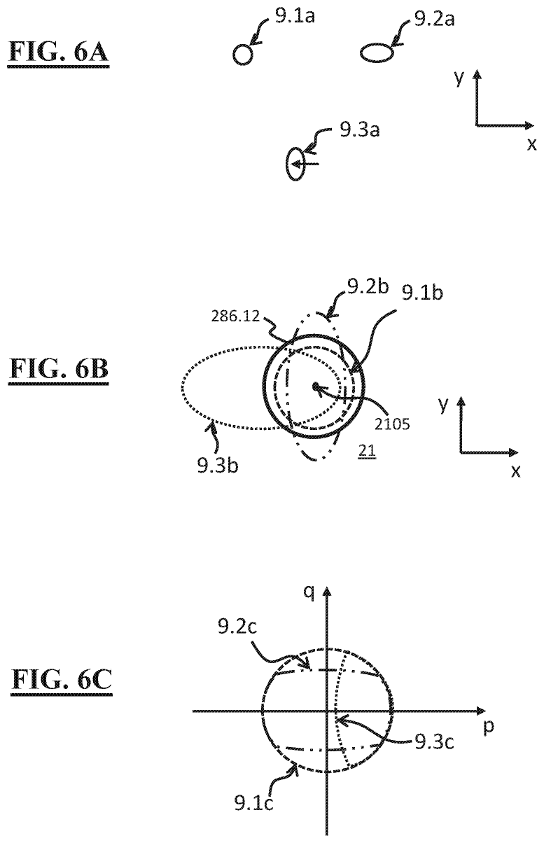

With any of the anisotropic aperture filters 284a to 284d, anisotropic filtering of the pronounced angular spectrum distributions is enabled, and the imaging contrast of semiconductor structures or metal lines is increased. By the arrangement of the common anisotropic aperture filters 284a to 284d in a common pupil position 2105 of the plurality of secondary electron beamlets 9, an anisotropic filter operation is performed for each of the plurality of secondary electron beamlets 9. In a second example of the first embodiment, an individual anisotropic filtering of individual secondary beamlets 9 is enabled. According to a second example, each secondary electron beamlet 9 is individually manipulated by the active array element 216. An example of an active array element 216 is illustrated in FIG. 5. The active array element 216 is formed as a multi-aperture plate 689, comprising a plurality of apertures 685 (only two are identified by 685.1 and 685.2). The apertures 685 are transmit the plurality of secondary electron beamlets in proximity to an intermediate image plane 211 of the detection unit 200 (see FIG. 1) at a position, where the secondary electron beamlets 9 are still separated from each other. At each aperture 685, two or more electrodes 681, for example eight electrodes 681.1 to 681.8 are provided, which are connected with the contrast control module 870 via voltage supply lines 687 (not all shown). During operation in a selected contrast mechanism, each individual secondary charged particle beamlet 9 can be shaped in an anisotropic form by the corresponding electrodes 681 of the corresponding aperture 685, such that a secondary electron beamlet 9 is for example shaped into an elliptical form or deflected into a specific off axis direction. The individually anisotropically shaped secondary electron beamlets 9 are transmitted downstream an aperture filter 284 in the common pupil plane 2105, for example circular aperture filter 284f FIGS. 6A-6C illustrate the effect at three examples. FIG. 6A shows the focus spots of the three secondary electron beamlets in an image plane of the detection unit 200. A first secondary electron beamlet 9.1a is not anisotropically shaped, but just transmits its corresponding aperture 685 in active array element 216 without any shaping. A second secondary electron beamlet 9.2a is anisotropically shaped into elliptical form in an image plane by application of corresponding voltages to at least four of the eight electrodes 681 arranged at the corresponding aperture of the second secondary electron beamlet 9.2. A third secondary electron beamlet 9.3a is anisotropically shaped into elliptical form and displaced in an image plane by application of corresponding voltages to at least four of the eight electrodes 681 arranged at the corresponding aperture of the third secondary electron beamlet 9.2. The corresponding voltages to at least four of the eight electrodes 681 are configured and selected to generate an anisotropic shape of the secondary electron beamlet 9.2 or 9.3. FIG. 6B illustrates the corresponding angular spectrum distributions 9.1b to 9.3b of each beamlet, wherein each of it is filtered by the common circular aperture opening 286.12. The second secondary electron beamlet 9.2 is filtered at the aperture opening 286.12, such that the angular spectrum of secondary electron beamlet 9.2 is blocked at regions of large angle in positive as well as negative y-direction. The third secondary electron beamlet 9.3 only passes the aperture opening 286.12 at regions of large angles in positive x-direction. FIG. 6C illustrates the effect of the filtering operation on the angular spectrum of the secondary electron beamlets 9.1 to 9.3 in the angular spectrum representation with angular spectrum coordinates p and q. The transmitted angular spectrum is therefore individually influenced by the combined action of the active array element 216 with a common aperture filter 284f, such that in this example, the full angular spectrum of the first secondary electron beamlet 9.1 is detected, while of the second secondary electron beamlet 9.2 and the third secondary electron beamlet 9.3 only partial angular spectrums are detected. Thereby, an image contrast can be improved individually for each beamlet in a similar way as described for the first example of the first embodiment. The common aperture filter 284 can have a single circular aperture opening 286.12 or can have any other shape or number of openings, generally depending on the inspection tasks on multiple different image segments according to the image segments generated by scanning the plurality of primary charged particle beamlets 3. Generally, other shapes of apertures 284 as shown in FIG. 2 are possible as well, for example dipole apertures, annular apertures, or apertures having five openings similar to aperture filters 284a or 284b with an additional axial opening.

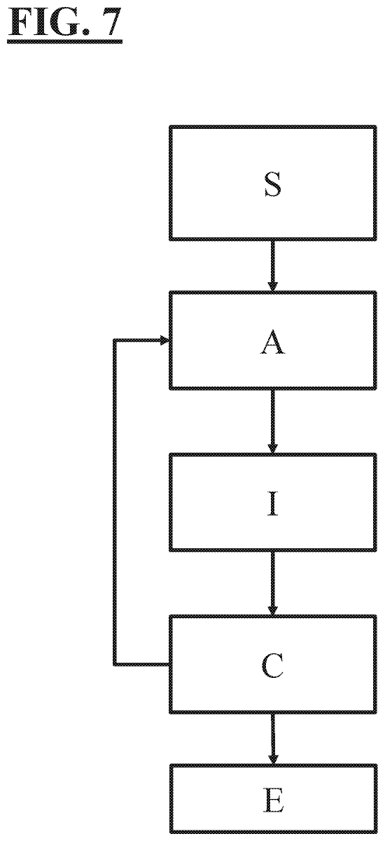

With such a system, a multi-beam inspection with enhanced image contrast is enabled. In some embodiments of the disclosure, a method of image enhancement for multi-beam image acquisition and wafer inspection is provided. An example is illustrated in FIG. 7.

In step S, an inspection site is selected and a surface 25 of a wafer 7 is placed by stage 500 in the image plane 101 of the multi-beam charged particle beam system 1.

In step A, a first contrast mechanism is selected, and a corresponding aperture filter 284 is placed into the common pupil plane 2105 of a detection unit 200 of the multi-beam charged particle beam system 1. The aperture filter 284 is for example placed by movement mechanism 215. Optionally, voltages for the plurality of electrodes 681 arranged at the apertures 685 of an active array element 216 are provided for individually shaping secondary electron beamlets 9 to adjust for at least a first and a second contrast mechanism for at least a first and a second secondary electron beamlet 9.

In an example, the selected contrast mechanism at the inspection position is determined according to prior information, including one of a previously determined selected contrast mechanism at an equivalent inspection position or from CAD information about semiconductor features at the inspection position of the wafer.

At step I, a scanning microscope image is obtained by scanning the plurality of primary charged particle beamlets 3 over the surface 25 of the wafer 7 and collecting the corresponding secondary electron signals with sensor unit 600. The image data generated by sensor 600 is collected by imaging control unit 810, further processed for example by image processing, stitching and other operations and optionally stored in the image memory part of memory 880.

In step C, the image contrast is evaluated. Optionally, if the image contrast according to the selected first or second contrast mechanisms in step A is not according to a predetermined expectation or desired property, an improvement of aperture filter selection and voltage generation for the plurality of electrodes 681 is performed and the method continues with step A. The process can be repeated iteratively until the predetermined expectation or desired property on image contrast is achieved. The finally obtained optimized contrast mechanisms can be stored as third and fourth or further contrast mechanism for a specific inspection task, optionally individually for each or the plurality of charged particle beamlets 3.

The first and second contrast mechanism can be initial contrast mechanisms, using for example standard circular apertures 284e and the determination of the optimum aperture filter 284 together with individual anisotropic beam shaping with active array element 216 can be determined in this way by iteratively optimizing the image contrast for each image segment obtained with each primary charged particle beamlet 3 and corresponding secondary electron beamlet 9. The optimized contrast mechanism can be stored for repetitive application of the same inspection task at similar inspection positions.

In an example, a selected aperture filter with anisotropic shape is positioned in the common pupil plane 21 of the detection unit 200. During an optimization of the image contrast for each of the secondary electron beamlets, voltages are provided to the active array element 216. The plurality of voltages are changed and a change in image contrast is determined. By iterative application of this method, an image contrast is optimized for each of the secondary electron beamlets.

In step E, the final inspection task is performed, and the inspection result is for example stored in memory 880 or visualized by a user interface. The inspection result of for example several inspection positions one a wafer can be evaluated and used for process optimization of the semiconductor manufacturing process.

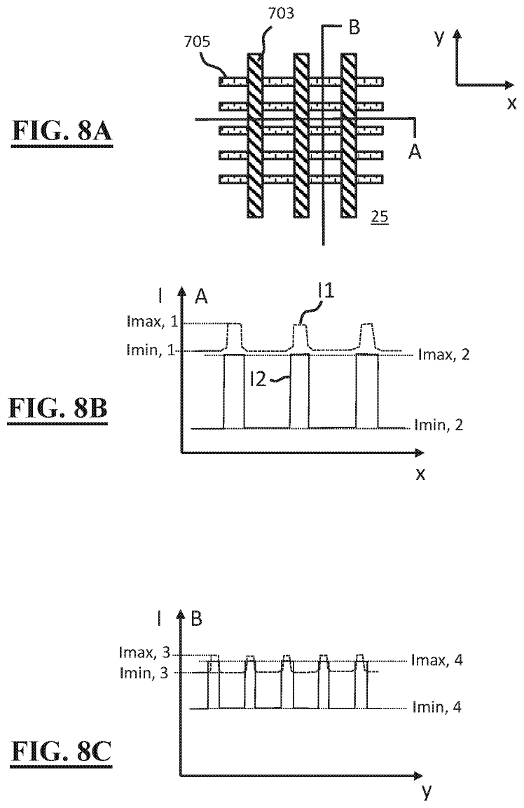

FIGS. 8A-8C illustrate results of the method according the second embodiment. FIG. 8A shows a simplified semiconductor structure haven horizontal and vertical elements such as gate fins 703 and channel fins 705. Two intersection images along lines A and B obtained by a multi-beam charged particle system 1 without and with the method of image enhancement are illustrated in FIGS. 8B and 8C.

In FIG. 8B, an image contrast obtained by a standard contrast mechanism with circular aperture 284e along line A is shown. The intensity signal I1 has a maximum intensity Imax,1 at the gate fins 703 with a strong background intensity Imin,1, leading to a low contrast C1. The contrast C is for example defined by C=(Imax−Imin)/(Imax+Imin). After application of elongated aperture filter 284c, the overall intensity is reduced, but the background signal is even more reduced, such that the contrast C2 computed from Imax,2 and Imin,2 is larger compared to C1. Typically, the contrast mechanism according to the disclosure improves the image contrast C2 by at least 10% over the image contrast C1 of the standard contrast mechanism. In examples, the contrast C2 is even further improved, for example by more than 20%, for example about 30%.

In addition to the overall contrast improvement, topography effects at the edges of example gate fins 703 are reduced and a rounding effect at images of edges are reduced. With the improved contrast mechanism according to the disclosure it is possible to obtain a larger normalized image log slope (NILS) of the residual digital images. Thereby, for example measurement tasks can be performed with higher accuracy.

In FIG. 8C, an image contrast obtained by standard contrast mechanism with circular aperture 284e along line B is shown. The intensity signal 13 has a maximum intensity Imax,3 at the channel fins 705 with a strong background intensity Imin,3, leading to a low contrast C3. After application of elongated aperture filter 284d, with an opening 286.10 perpendicular to opening 286.9 of aperture filter 284c, the overall intensity is again reduced, but the background signal is even more reduced, such that the contrast C4 computed from Imax,4 and Imin,4 is larger compared to C3.

Thereby, by for example individually shaping secondary electron beamlets 9 with active array element 216 of a multi-beam charged particle beam system 1 it is possible to obtain in parallel high contrast images of gate fins 703 and channel fins 705 during the performance of one inspection task at no additional expenses of the image sensor unit 600, and at a small increase of image noise only compared to using a multi-sensor array of the prior art with many individual images sensors for each secondary electron beamlet 9. The system and method according to the disclosure can therefore allow the application of improved contrast mechanisms with minimal impact on a multi-beam charged particle beam system 1, including reduced energy consumption, reduced amount of computation efforts and reduced amount of memory for processing and storing the generated image data with for example only one sensor for each secondary electron beamlet. Of course, an improved contrast mechanism according to the disclosure can nevertheless be combined with an image sensor array comprising multiple individual sensor elements for each secondary electron beamlet and the benefits of the improved image contrast can be exploited there as well.

Generally, by for example individually shaping secondary electron beamlets 9 in an anisotropic form with active array element 216 of a multi-beam charged particle beam system 1 it is possible to obtain for each of the secondary electron beamlets 9 an imaging with high contrast images for different areas on a wafer surface. For example, in logic devices, different subfields corresponding to a primary or secondary electron beamlet can comprise different semiconductor features with different charging properties or different topography. Special process control monitors (PCM) can be arranged according to the raster of the plurality of beamlets, and specific process performance indicators of different semiconductor features can be measured in parallel with individually enhanced image contrast for each beamlet of a multi-beam charged particle beam system 1. Thereby, a higher throughput of a wafer inspection task is enabled.

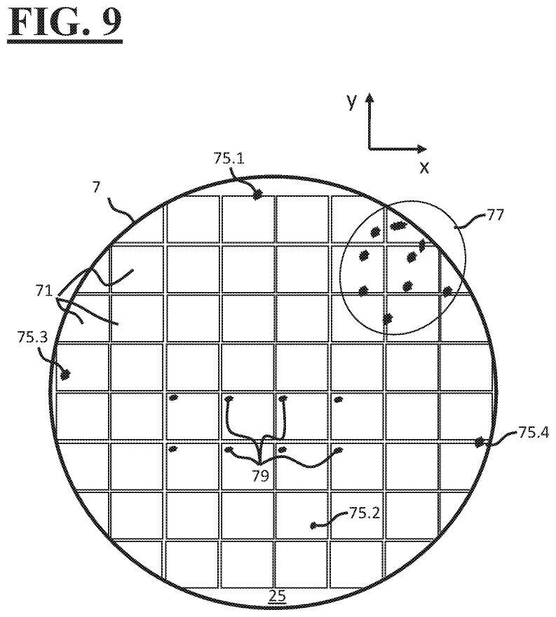

FIG. 9 illustrates an example of a result of Step E. A processed wafer 7 typically comprises several dies 71 arranged in rows and columns. Each die 71 corresponds to one lithography exposure with a semiconductor mask. Within each die 71, at least one semiconductor element is arranged, for example a processor or a memory element. With a multi-beam charged particle beam system 1, large areas of a wafer surface 25 can be inspected in shorter time, and for example properties of semiconductor features such as fins, interconnections, HAR channels, transistor gates, doped areas, process control monitors, and the like, can be measured in shorter time. Furthermore, defects can be detected, for example defects arising from contamination during wafer processing, or mask defects. FIG. 9 illustrates some example of measurement results. A number of first, random defects 75.1 to 75.4 is scattered over the wafer surface 25, may be a result of random particle defects. A cluster of defects 77 at the wafer border may be an indicator of a deviation in a specific process step. Repetitive deviations 79 may be an indicator of a mask defect or contamination. During step E, the result of a plurality of inspection tasks on a single wafer or a group of wafers is analyzed for random defects 75, characteristic clusters of defects 77 or repetitive defects 79. The result can trigger a fabrication process improvement, for example a mask repair operation, a cleaning operation, or an adjustment of fabrication process parameters of an individual fabrication process step during wafer fabrication.

The features of the embodiments can improve the performance, especially the image contrast of a multi-beam charged particle system 1 to achieve large image contrast at image resolutions of below 5 nm, such as below 3 nm, for example below 2 nm or even below 1 nm. The improvements can be utilized for a further development of multi-beam charged particle systems with a larger number of the plurality of primary beamlets such as more than 100 beamlets, more than 300 beamlets, more than 1000 beamlets or even more than 10000 beamlets. The improvements can be utilized for routine applications of multi-beam charged particle systems, for example in semiconductor inspection and review, where high image contrast, high reliability and high reproducibility and low machine-to-machine deviations are usually desired. With the features described in the embodiments as well as combinations thereof, each beamlet of the plurality of beamlets is provided with increased imaging performance.

The disclosure is further described by following clauses:

Clause 1: A multi-beam charged particle beam system (1) for wafer inspection, comprising:
an object irradiation unit (100), comprising a multi-beamlet generator (300) for generating a plurality of primary charged particle beamlets (3) and an objective lens (102) for focusing during use the plurality of primary charged particle beamlets (3) into an image plane (101) of the object irradiation unit (100);
a detection unit (200) configured for imaging a plurality of secondary electron beamlets (9), which are generated in parallel during use at the interaction volumes (707) of the plurality of primary charged particle beamlets (3) with a surface (25) of a wafer (7) onto an image sensor (600), wherein the detection unit (200) is comprising an aperture filter module (214) comprising at least one aperture filter (284) for anisotropic filtering at least one secondary electron beamlet (9);
a beam splitter unit (400) for guiding the plurality of primary charged particle beamlets (3) from the multi-beamlet generator (300) to the objective lens (102) and for guiding the plurality of secondary electron beamlets (9) from the objective lens (102) to the detection unit (200);
control unit (800) comprising a contrast control module (870) configured for controlling during use an anisotropic filtering of at least one of the plurality of secondary electron beamlets (9) with the at least one aperture filter (284) of the aperture filter module (214).

Clause 2: The system of clause 1, wherein the aperture filter module (214) is comprising a movement mechanism (215) configured for exchanging the at least one aperture filter (284), and wherein the contrast control module (870) is configured for selecting and positioning during use a selected aperture filter (284) with the movement mechanism (215) in a common pupil plane (21) of the detection unit (200).

Clause 3: The system of clause 1 or 2, wherein the selected aperture filter (284) comprises an aperture opening (286c, 286d) of anisotropic shape, for example of elliptical or elongated rectangular shape.

Clause 4: The system of clause 1 or 2, wherein the selected aperture filter (284) comprises a plurality of aperture openings (286.1 to 286.8) configured to be arranged outside of an electron optical axis (2105) of the detection unit (200).

Clause 5: The system of clause 4, wherein, in the selected aperture filter (284), at least two or four aperture openings (286.1 to 286.4) are arranged symmetrically with respect to the electron optical axis (2105), forming an aperture filter (284) with dipole or quadrupole shape.

Clause 6: The system of clause 5, wherein contrast control module (870) is configured to arrange the selected aperture filter (284) with dipole or quadrupole shape according to the horizontal or vertical structures (728,729,731) of semiconductor features in a wafer (7).

Clause 7: The system of clause 5, wherein contrast control module (870) is configured to arrange the selected aperture filter (284) with dipole or quadrupole shape according to a topography of semiconductor features (703, 705) in a wafer (7).

Clause 8: The system of any of the clauses 1 to 7, wherein the detection unit (200) comprises a plurality of electron-optical elements (205), configured for forming an intermediate image plane (211) of the plurality of secondary electron beamlets (9) and an active multi-aperture array (216) in proximity to the intermediate image plane (211), the active multi-aperture array (216) comprising a plurality of apertures (685), each for passage of one of the plurality of secondary electron beamlets (9), each of the apertures (685) configured with a plurality of electrodes (681) connected to the contrast control module (870), configured for individually anisotropic shaping or deflecting during use at least one of the secondary electron beamlets (9).

Clause 9: The system of clause 8, wherein the contrast control module (870) is configured for controlling the active multi-aperture array (216) for a first anisotropic shaping or deflecting a first secondary electron beamlet (9.2) and for a second anisotropic shaping or deflecting a second secondary electron beamlet (9.3); and is configured to arrange an aperture filter (284e, 2840 of circular shape in the common pupil plane (21).

Clause 10: The system of any of the clause 1 to 9, further comprising a voltage supply unit (503) connected to a wafer for providing during use a voltage to the wafer for generating a decelerating field for primary charged particles, corresponding to an accelerating field for secondary electrons generated in the interaction volumes (707).

Clause 11: A method of contrast improvement for a wafer inspection task, comprising:
illuminating, with a plurality of primary charged particle beamlets (3) of a multi-beam charged particle beam system (1), a surface (25) of a wafer (7), thereby exciting a plurality of secondary electron beamlets (9) from interaction volumes (707) generated by the plurality of primary charged particle beamlets (3) and the wafer (7),
collecting the plurality of secondary electron beamlets (9) with an objective lens (102),
anisotropic filtering at least one of the secondary electron beamlets (9) by a selected aperture filter (284) arranged in a common pupil plane (21) of a detection unit (200) of the multi-beam charged particle beam system (1),
collecting the signals of each of the plurality of secondary electron beamlets (9) with an image sensor (600), including the at least one anisotropically filtered secondary electron beamlet (9.2,9.3), for generating an image of a surface (25) of a wafer (7) with enhanced contrast.

Clause 12: The method of clause 11, further comprising
selecting the selected aperture filter (285), and
positioning the selected aperture filter (285) with a movement mechanism (215) in the common pupil plane (21) of the detection unit (200).

Clause 13: The method of clause 11 or 12, further comprising the step of providing to at least one electrode (681) of an active array element (216) arranged within the detection unit (200) a voltage to anisotropically shape or deflect at least one of the secondary electron beamlets (9).

Clause 14: The method of any of the clauses 11 to 13, further comprising
arranging, with a wafer stage (500), an inspection position of a surface (25) of a wafer (7) in the image plane (101) of the multi-beam charged particle beam system (1),
determining a selected contrast mechanism at the inspection position,
selecting and providing the preselected aperture filter (284) and at least one of a plurality of voltages to an active array element (216) for anisotropically filtering at least one of the secondary electron beamlets (9) according to the selected contrast mechanism,
performing an image acquisition of the surface (25) of a wafer (7) to acquire a digital image of semiconductor features (728, 703, 705) of the wafer (7) at the inspection position.

Clause 15: The method of clause 14, wherein the selected contrast mechanism at the inspection position is determined according to prior information, including one of a previously determined selected contrast mechanism at an equivalent inspection position or from CAD information.

Clause 16: The method of clause 14, further comprising
evaluating a first image contrast of the digital image,
modifying the selected contrast mechanism by modifying at least one of the preselected aperture filter (284) or a voltage provided to an electrode of the active array element (216),
determining an improved contrast mechanism with improved image contrast compared to the first image contrast.

Clause 17: The method of clause 16, further comprising the step of storing the improved contrast mechanism for use with the inspection position.

Clause 18: The method of any of the clauses 11 to 16, further comprising
performing an image evaluation of the digital image of semiconductor features (728, 703, 705) of the wafer (7) to determine a defect comprising at least one of a deviation of a size, an area, a material composition of a semiconductor feature (728, 703, 705), or a contamination particle.

Clause 19: The method of clause 18, further comprising
repeating the image acquisition of the surface (25) of a wafer (7) at plural inspection positions,
evaluating a distribution of defects to determine at least one of random defects, regular defects or clusters of defects.

The disclosure is however not limited to the embodiments or clauses described above. The embodiments or examples can be fully or partly combined with one another, and numerous variations and modifications are possible.

A list of reference numbers is provided:
1 multi-beamlet charged-particle system
3 primary charged particle beamlets, or plurality of primary charged particle beamlets
5 primary charged particle beam spot
7 wafer
9 secondary electron beamlet, forming the plurality of secondary electron beamlets
11 secondary electron beam path
13 primary beam path
15 secondary charged particle image spot
21 common pupil plane
25 surface of wafer
71 die
75 isolated random defects
77 cluster of defects
79 regular defects
100 object irradiation unit
101 image plane
102 objective lens
103 field lens
108 first beam cross over
110 collective multi-beam raster scanner
200 detection unit
205 lens element
211 intermediate image plane
214 aperture filter module
215 movement mechanism
216 active array element
222 second deflection system
284 aperture filter
286 aperture opening
300 charged-particle multi-beamlet generator
301 charged particle source
303 collimating lenses
304 filter plate
305 primary multi-beamlet-forming unit
306 multi-aperture plates
307 terminating multi-aperture plate
308 field lenses
309 primary electron beam
321 intermediate image surface
400 beam splitter unit
500 sample stage
503 Sample voltage supply
505 decelerating or extraction field, illustrated by equipotential lines
600 image sensor
681 electrodes
685 aperture
687 voltage supply lines
689 multi aperture plate
703 Gate Fin
705 Channel Fin
707 Interaction volume
711 layers of a wafer
728 conducting elements if first layer
729 conducting elements if second layer
731 conducting elements if third layer
800 control unit
810 imaging control module
820 secondary beam-path control module
830 primary beam-path control module
840 Control operation processor
850 stage control module
860 scanning operation control module
870 contrast mechanism control module
880 memory
2105 common pupil position

What is claimed is:

1. A multi-beam charged particle beam system, comprising:
an object irradiation unit, comprising:
a multi-beamlet generator configured to generate a plurality of primary charged particle beamlets; and
an objective lens configured to focus the plurality of primary charged particle beamlets into an image plane of the object irradiation unit;
a detection unit configured to image a plurality of secondary electron beamlets generated via interaction of the plurality of primary charged particle beamlets with a surface of a wafer onto an image sensor, wherein the detection unit comprises an aperture filter module comprising an aperture filter configured to anisotropically filter at least one secondary electron beamlet;
a beam splitter unit configured to guide the plurality of primary charged particle beamlets from the multi-beamlet generator to the objective lens and to guide the plurality of secondary electron beamlets from the objective lens to the detection unit; and
a control unit comprising a contrast control module configured to control anisotropic filtering of the at least one of the plurality of secondary electron beamlets via the aperture filter.

2. The multi-beam charged particle beam system of claim 1, wherein the aperture filter module comprises a movement mechanism configured to exchange the aperture filter, and the contrast control module is configured to select and position the aperture filter via the movement mechanism in a common pupil plane of the detection unit.

3. The multi-beam charged particle beam system of claim 1, wherein the aperture filter comprises an anisotropically shaped aperture opening.

4. The multi-beam charged particle beam system of claim 1, wherein the aperture filter comprises a member selected from the group consisting of an elliptical aperture filter and an elongated rectangular aperture filter.

5. The multi-beam charged particle beam system of claim 1, wherein the aperture filter comprises a plurality of aperture openings outside an electron optical axis of the detection unit.

6. The multi-beam charged particle beam system of claim 5, wherein at least two of the plurality of aperture openings are disposed symmetrically with respect to the electron optical axis to provide an aperture filter with a shape selected from the group consisting of a dipole shape and a quadrupole shape.

7. The multi-beam charged particle beam system of claim 6, wherein the contrast control module is configured to arrange the aperture filter with the shape based on structures of semiconductor features in the wafer that are selected from the group consisting of horizontal structures and vertical structures.

8. The multi-beam charged particle beam system of claim 6, wherein the contrast control module is configured to arrange the aperture filter with the shape based on a topography of semiconductor features in the wafer.

9. The multi-beam charged particle beam system of claim 1, wherein the detection unit comprises:
a plurality of electron-optical elements configured to provide an intermediate image plane of the plurality of secondary electron beamlets; and
an active multi-aperture array in proximity to the intermediate image plane, the active multi-aperture array comprising a plurality of apertures, each aperture of the multi-aperture array configured to pass one of the plurality of secondary electron beamlets, each aperture of the multi-aperture array comprising a plurality of electrodes connected to the contrast control module to individually anisotropically shape or deflect the one of the plurality of secondary beamlets that passes therethrough.

10. The multi-beam charged particle beam system of claim 9, wherein:
the contrast control module is configured to control the active multi-aperture array to: i) anisotropically shape or deflect a first secondary electron beamlet; and anisotropically shape or deflect of a second secondary electron beamlet; and
the contrast control module is configured to arrange a circular aperture filter in a common pupil plane of the detection unit.

11. The multi-beam charged particle beam system of claim 1, further comprising a voltage supply unit configured to be connected to the wafer to provide a voltage to the wafer to generate a decelerating field for primary charged particles, corresponding to an accelerating field for the secondary electrons.

12. A method, comprising:
using a plurality of primary charged particle beamlets of a multi-beam charged particle beam system to illuminate a surface of a wafer to generate a plurality of secondary electron beamlets generated by the plurality of primary charged particle beamlets and the wafer;
using an objective lens to collect the plurality of secondary electron beamlets;
using a selected aperture filter arranged in a common pupil plane of a detection unit of the multi-beam charged particle beam system to anisotropically filter a secondary electron beamlet; and
using an image sensor to collect the signals of each of the plurality of secondary electron beamlets, including the anisotropically filtered secondary electron beamlet, to generate an image of a surface of the wafer.

13. The method of claim 12, further comprising:
selecting the aperture filter; and
positioning the selected aperture filter in the common pupil plane of the detection unit.

14. The method of claim 12, further comprising providing a voltage to an electrode of an active array element arranged within the detection unit to anisotropically shape or deflect at least one of the secondary electron beamlets.

15. The method of claim 12, further comprising:
arranging an inspection position of a surface of the wafer in the image plane of the multi-beam charged particle beam system;
determining a selected contrast mechanism at the inspection position;
selecting and providing the aperture filter and at least voltage to an active array element to anisotropically filter at least one of the secondary electron beamlets according to the selected contrast mechanism; and
performing an image acquisition of the surface of the wafer to acquire a digital image of semiconductor features of the wafer at the inspection position.

16. The method of claim 15, wherein the selected contrast mechanism at the inspection position is determined according to information comprising a member selected from the group consisting of: i) a previously determined selected contrast mechanism at an equivalent inspection position; and ii) CAD information.

17. The method of claim 15, further comprising:
evaluating a first image contrast of the digital image;
modifying the selected contrast mechanism by modifying at least one member selected from the group consisting of the preselected aperture filter and a voltage provided to an electrode of the active array element; and
determining a second contrast mechanism with improved image contrast compared to the first image contrast.

18. The method of claim 17, further comprising storing the second contrast mechanism to be used with the inspection position.

19. The method of claim 17, further comprising performing an image evaluation of the digital image of semiconductor features of the wafer to determine a defect comprising at least one member selected from the group consisting of a deviation of a size of a semiconductor feature, a deviation of an area of a semiconductor feature, a deviation of a material composition of a semiconductor feature, and a contamination particle.

20. The method of claim 19, further comprising:
repeating the image acquisition of the surface of the wafer at plural inspection positions; and
evaluating a distribution of defects to determine at least one member selected from the group consisting of random defects, regular defects, and clusters of defects.
